(19) United States
(12) Patent Application Publication
(10) Pub. No.: US 2020/0328319 A1
(43) Pub. Date: Oct. 15, 2020

(54) Multi-Junction Solar Cell, Its Fabrication and Its Use

(71) Applicant: Imperial Innovations Limited, London (GB)

(72) Inventors: Alexander Mellor, London (GB); Nicholas Hylton, London (GB); Nicholas Ekins-Dawkes, London (GB)

(21) Appl. No.: 16/306,410

(22) PCT Filed: Jun. 1, 2017
(86) PCT No.: PCT/GB2017/051581

§ 371 Date: Nov. 30, 2018

(30) Foreign Application Priority Data
Jun. 1, 2016 (GB) 1609557.2

(51) Int. Cl. H01L 31/0687; H01L 31/0216; H01L 31/043; H01L 31/054; H01L 31/055; H01L 31/048; H01L 31/0725

(52) U.S. Cl. CPC H01L 31/06875; H01L 31/02168; H01L 31/043; H01L 31/0725; H01L 31/055; H01L 31/0481; H01L 31/0547

(57) ABSTRACT

There is provided a multi-junction solar cell comprising: a target subcell, a diffraction grating, a transparent spacer layer, a distributed Bragg reflector, and a lower subcell.

### CROSS-REFERENCE TO RELATED APPLICATIONS

This application is a national stage application under 35 U.S.C. § 371 of International Patent Application no. PCT/GB2017/051581, filed Jun. 1, 2017, which claims the benefit of priority of United Kingdom Patent Application no. 1609557.2, filed Jun. 1, 2016.

### TECHNICAL FIELD

This invention relates to a high efficiency multi-junction solar cell that incorporates light-trapping structures for enhancing the photocurrent of the device.

### BACKGROUND

The invention relates to high-efficiency III-V multi-junction solar cells, and in particular using a combination of photonic micro- and nano-structures to improve photocurrent generation.

A solar cell is a device that converts incident sunlight into electrical power. The sunlight is incident on one face of the device. Sunlight consists of a spectrum of photons with a range of wavelengths. A given photon has a specific wavelength, A, and a specific energy, Eₚₕₒₜ, which are inversely proportional according to the relation

$${E}_{phot} = \frac{h c}{λ}$$

The type of solar cell referred to in this document uses semiconductor materials to convert sunlight into electrical power. When a photon passes through a semiconductor material, it is able to create a pair of charge carriers. The photon is annihilated in this process, and is said to be absorbed by the semiconductor. The charge carriers are said to be photogenerated. In a solar cell, photogenerated charge carriers are extracted as an electrical current which can produce electrical power.

In a given semiconductor material, a photon can only photogenerate charge carriers if its energy is higher than the so-called bandgap of that material. The bandgap has units of energy and is specific to the material. Photons with energies that are higher than the bandgap are absorbed strongly by the semiconductor material and cause photogeneration of carriers. Photons with energies lower than the bandgap are not absorbed strongly by the semiconductor material. A semiconductor therefore absorbs photons with an energy range, whose lower energy limit is set by the bandgap. Equivalently, a semiconductor absorbs photons with a wavelength range, whose upper wavelength limit is set by the bandgap.

Multi-junction solar cells consist of a stack of two or more subcells based on different semiconductor materials. Each subcell is responsible for absorbing a different wavelength-range of the incident solar spectrum and converting it to electrical power. This is achieved by using different materials with bandgaps that cascade from high energy to low energy from the top of the device to the bottom. The subcell at the top of the device absorbs all photons with energies that are greater than its bandgap, but allows photons with energies lower than its bandgap to pass to the cell below. The cell below therefore absorbs all photons with energies higher than its bandgap, but lower than the bandgap of the cell above it. This is true of all subcells, and therefore each subcell absorbs a wavelength range of photons. The wavelength range of a given subcell is unique to that subcell, and is hereafter referred to as the wavelength range of the subcell. It is important that the device is designed so that photons in the wavelength range of a given subcell are not absorbed in the subcell below it, since this will result in an efficiency loss.

Multi-junction solar cells are presently the highest efficiency photovoltaic (PV) technology. Under concentrated terrestrial sunlight, an efficiency of 46% has been reported for a wafer-bonded GaInP/GaAs; GaInAsP/GaInAs solar cell (see Green, M. et al, Solar cell efficiency tables (Version 45),” Progress in Photovoltaics: Research and Applications, 23(1), 1-9 (2015); an efficiency of 44% has been reported for a monolithic GaInP/GaAs/GaInNAs solar cell (see Green, M. et al, Solar cell efficiency tables (version 41),” Progress in Photovoltaics: Research and Applications, 21(1), 1-11 (2012); and an efficiency of 43.5% has been reported for an inverted metamorphic InGaP/GaAs/InGaAs solar cell. Under un-concentrated extraterrestrial sunlight an efficiency of 29.2% has been reported for a monolithic InGaP/InGaAs/Ge solar cell. The InGaP/InGaAs/Ge solar cell is presently used in almost all space flights.

The thickness of each subcell is designed as a trade-off between two competing demands. Firstly, the thickness must be large enough so that nearly 100% of photons in the corresponding wavelength range are absorbed in the subcell. Secondly, the thickness must be small enough so that nearly 100% of photogenerated carriers can be efficiently collected from the device before they recombine. If the carrier diffusion length is too low compared to the penetration depth of photons in the material-, a good trade-off cannot be found and the efficiency of the solar cell suffers as a result.

Many III-V subcells in existing technologies suffer from low diffusion lengths, either due to intrinsic properties of the material, or due to strain accumulation caused by the necessity to grow the material monolithically with other materials with different lattice constants.

In space, this problem is exacerbated since the solar cells are subject to radiation damage by high-energy irradiation, which causes material degradation, leading to a reduction in carrier diffusion lengths, and therefore a reduction in photocurrent. In the InGaP/InGaAs/Ge solar cells presently used in space, this effect is most pronounced for the InGaAs middle cell, which limits the total current generation at the end of space missions (see Yamaguchi, M et al. Super-high-efficiency multi-junction solar cells, Progress in Photovoltaics: Research and Applications, 13(2), 125-132 (2005)). Improving the so-called radiation hardness of solar cells, i.e., mitigating the efficiency loss caused by radiation damage, is a key activity in the ongoing development of space solar cells (Caon. A et al., “Solar Generators for ESA Missions: in Orbit Performance and Future Challenges. (1979-1985).

In single-junction solar cells, the problem of an unfavourable carrier diffusion length to photon penetration depth ratio has been addressed using so-called light-trapping techniques. Optical structures are incorporated into the solar cell, which increase the optical path length within the absorber layer. This allows absorption to be increased for a given layer thickness, or, allows the thickness to be reduced while maintaining high absorption; hence, the demands of near 100% absorption and near 100% carrier collection can be satisfied simultaneously.

Light-trapping structures consist of a combination of a rear reflector and a textured surface (or surfaces). The rear reflector prevents photons escaping the solar cell at the rear. The textured surface deflects photons obliquely within the absorbing material, which increases their path length, and causes many photons to be totally internally reflected at the front surface. The combination causes photons to make multiple passes of the absorber layer thus increasing the absorption.

One means of achieving light trapping is to incorporate diffraction gratings into the solar cells, since they can deflect incident photons into oblique trajectories within the absorbing medium. In this context, the diffraction grating may consist of a layer of material that is textured with a periodic relief; or of a periodic array of isolated particles. In both cases, the constituent materials of the layer or particles may be semiconductor, metal or dielectric.

The type of light trapping structure that is applied to single-junction solar cells cannot be directly applied to multi-junction solar cells due to their architecture. This is particularly true if the subcell to be enhanced by light trapping is not the bottom-most subcell in the device. Photons in the wavelength range that corresponds to a particular subcell cannot be allowed to penetrate into a lower subcell, since they will be absorbed in the lower subcell causing an efficiency loss. Hence, a reflector must be located between the target subcell and the subcell beneath it. This reflector must be wavelength selective, since the wavelength range corresponding to the lower subcell must be transmitted through the reflector to the lower subcell.

Conversely, it is not problematic for photons in the wavelength range that corresponds to a particular subcell to make multiple passes of an upper subcell, since, by the design of the multi-junction solar cell, all upper subcells are transparent in the wavelength range of the aforementioned particular subcell.

Wavelength-selective reflection can be achieved by a distributed Bragg reflector hereafter referred to as DBR. This is an optical component consisting of alternating layers of two materials with different refractive indices. The DBR is reflective over a specific wavelength range, known as the stop-band, and is transmissive at other wavelengths outside that range. The central wavelength of the stop-band can be controlled via the thicknesses of the layers of the DBR.

A DBR is only effective in reflecting normally incident photons. Hence, a simple combination of a surface texture and a DBR will not lead to effective light trapping, since photons deflected obliquely by the surface texture will not be reflected by the DBR.

### SUMMARY OF THE INVENTION

There is provided a multi-junction solar cell comprising: a target subcell, a diffraction grating, a transparent spacer layer, a distributed Bragg reflector, and a lower subcell.

The target subcell may be above the lower subcell.

The transparent spacer layer may be below the target subcell, and the distributed Bragg reflector may be below the transparent spacer layer.

The transparent spacer layer and the distributed Bragg reflector may be above the lower subcell.

The diffraction grating may be below the target subcell, and the transparent spacer layer may be below the diffraction grating.

The diffraction grating may be at the top of the multi-junction solar cell.

The diffraction grating may be arranged to deflect an incident light beam with a trajectory perpendicular to a plane of the diffraction grating into diffraction orders having trajectories oblique with respect to said plane.

The target subcell has a first refractive index and the transparent spacer layer may have a second refractive index lower than the first refractive index.

At least one of the target subcell and the lower subcell may comprise group III-V materials.

The group III-V materials may be selected from the group consisting of InGaP, AlInP, GaAs, InGaAs, GaAsN, GaAsSb, GaAsNSb, GaAsInN, GaAsInNSb, GaAsBi, and GaAsBiN.

At least one of the target subcell and the lower subcell may comprise group IV materials.

The group IV materials may be selected from the group consisting of Ge, Si, SiGe, and SiGeSn.

The diffraction grating may be embedded in an anti-reflection coating.

The diffraction grating may comprise multiple layers with different refractive indices.

The diffraction grating may comprise a textured layer.

The textured layer may comprise a spatially-periodic array of isolated particles.

The textured layer may comprise a material selected from the group consisting of AlInP, GaInP, InGaAs, GaAs and Si.

The diffraction grating may comprise semiconductor materials selected from the group consisting of AlInP, GaInP and a-Si:H.

The diffraction grating may comprise metallic materials selected from the group consisting of Al, Ag and Au.

The diffraction grating may comprise a grating period in the range 200-1400 nm.

The multi-junction solar cell may further comprise an electrically insulating layer between the diffraction grating and the target subcell.

The transparent spacer layer may be selected from the group consisting of SiOx, TiOx, MgFx, TaOx, AlOx and SiN.

The transparent spacer layer may be an air gap.

The distributed Bragg reflector may comprise alternating layers of different semiconductor materials.

The distributed Bragg reflector may comprise alternating layers of different dielectric materials.

The distributed Bragg reflector may comprise two materials with different refractive indices, wherein one refractive index may be higher, and one refractive index may be lower than the other, wherein the higher refractive index material may be selected from the group consisting of GaAs, TiOx, TaOx and SiN.

The distributed Bragg reflector may comprise two materials with different refractive indices, wherein one refractive index may be higher, and one refractive index may be lower than the other, wherein the lower refractive index material may be selected from the group consisting of AlAs, GaInP, MgFx, SiO2 and AlOx.

The distributed Bragg reflector may comprise a combination of dielectric and semiconductor materials.

The multi-junction solar cell may be a four-terminal device.

The multi-junction solar cell may comprise a triple-junction InGaP/InGaAs/Ge space solar cell, formed of subcells comprising InGaP, InGaAs and Ge.

The transparent spacer layer, the diffraction grating and the distributed Bragg reflector may be positioned between the InGaAs subcell and the Ge subcell, wherein the target subcell may be the InGaAs subcell.

The thickness of the target subcell may be in the range 300-1000 nm.

The multi-junction solar cell may comprise anti-reflection layers between the target subcell and the lower subcell.

There is provided a method of fabricating a multi-junction solar cell as herein described wherein a two-substrate mechanical stacking process is combined with a nanotexturing deposition or a nanoparticle deposition process.

The nanoparticles may be arranged between the target subcell and the lower subcell.

The nanotexturing may be arranged between the target subcell and lower subcell.

The target subcell and the lower subcell may be grown on separate substrates and bonded together to form a mechanical stack with the distributed Bragg reflector and transparent spacer layer in-between the target subcell and the lower subcell.

There is provided use of a multi-junction solar cell as herein described in terrestrial applications, space applications, a concentrator voltaic module, a satellite, a solar panel or in terrestrial solar power generators.

There is also provided use of a multi-junction solar cell as herein described in a kit comprising a solar panel, a power subsystem; and a satellite.

### BRIEF DESCRIPTION OF THE DRAWINGS

Exemplary embodiments of the invention shall now be described with references to the drawings.

FIG. 1 is a schematic diagram of the multi-junction solar cell of the present invention in which the diffraction grating 4, the transparent spacer layer 5, and the DBR 6 are all located between two of the subcells of the device. This embodiment is denoted configuration a.

FIG. 2 is a schematic diagram of the multi-junction solar cell of the present invention in which the diffraction grating 4 is located on the top of the device, and in which the transparent spacer layer 5 and DBR 6 are both located between two of the subcells of the device. This embodiment is denoted configuration b.

FIG. 3 is a schematic diagram of configuration a of the multi-junction solar cell of the present invention, showing the photon trajectories for normally incident photons in the wavelength range of the target subcell 3.

FIG. 4 is a schematic diagram of configuration b of the multi-junction solar cell of the present invention, showing the photon trajectories for normally incident photons in the wavelength range of the target subcell 3.

FIG. 5 is a schematic diagram of the multi-junction solar cell in which the host solar cell is a triple-junction GaInP/InGaAs/Ge space solar cell. The optical components are located between the InGaAs and Ge subcells.

FIG. 6 is a graph showing the calculated photon absorption in a 700 nm thick InGaAs subcell of the invention depicted by the solid line, compared to the absorption in a 3500 nm thick InGaAs subcell in an equivalent control cell that does not incorporate the optical components that comprise the invention indicated by the dashed line.

The solid line in FIG. 7 shows the calculated InGaAs photocurrent in the invention as a function of high-energy (1 MeV) electron fluence. The dashed line in FIG. 7 shows the calculated InGaAs photocurrent in the control device as a function of high-energy (1 MeV) electron fluence.

FIG. 8 is a schematic of the GaInP/InGaAs/Ge control device, without optical components.

FIG. 9 is a schematic of the trajectories of photons in the wavelength range of the lower subcells 7 upon entering into the device in configuration a.

FIG. 10 is a schematic of the trajectories of photons in the wavelength range of the lower subcells 7 upon entering into the device in configuration b.

### DETAILED DESCRIPTION OF THE INVENTION

The invention relates to multi-junction solar cells comprising optical components that work in conjunction to increase the efficiency of the solar cells for both terrestrial and space applications. For space applications, the invention also serves to improve the radiation hardness of the solar cells.

Aspects and features of the invention are set out in the appended claims.

The device is considered to be oriented such that the faces of the device and the interfaces between the subcells are parallel with the horizontal plane, and photons from the sun enter the device from the top and propagate downwards towards the bottom. The top of the device is also referred to as the front and the bottom is also referred to as the rear.

A normal trajectory 9 is defined as a trajectory that is perpendicular to the horizontal plane. An oblique trajectory 8 is defined as a trajectory that is not perpendicular to the horizontal plane. The polar angle of a photon trajectory is defined as the angle between the trajectory and the direction that is perpendicular to the horizontal plane. In the following discussions, it is assumed that photons incident from the sun have normal trajectory 9 upon first penetrating into the device. This is justified as follows. In space applications, the device is at all times oriented such that photons incident from the sun have a polar angle of less than 5°. Due to refraction, the same photons have a polar angle inside the device of less than 2°. In terrestrial applications, the device is illuminated by concentrating optics, which illuminate the device with photons whose polar angle of less than 30°, for most practical systems. Due to refraction, the same photons have a polar angle inside the device of less than 10°.

The optical components aim specifically at improving the photocurrent of a subcell within the multi-junction stack. The subcell that has an enhanced photocurrent as a result of the effect of the optical components is hereby referred to as the target subcell 3. The target subcell 3 can be any of the subcells in the multi-junction stack, except for the lower-most subcell. The one or more subcells on top of the target subcell 3 are denoted the upper subcells 2. The one or more subcells behind the target subcell 3 are denoted the lower subcells 7. Embodiments of the invention may have any number of lower and upper subcells 2. There may also be zero upper subcells.

In one embodiment of the invention, a multi-junction solar cell is presented in which a diffraction grating 4 is located beneath the target subcell 3, a low-index transparent spacer layer 5 is positioned beneath the diffraction grating 4, and a DBR 6 is located beneath the low-index transparent spacer 5 layer and above the lower subcells 7. This embodiment is denoted configuration 1a.

In one embodiment, a multi-junction solar cell is presented comprising at least one upper subcell 2, a diffraction grating 4, a low-index transparent spacer 5, a distributed Bragg reflector, and at least one lower subcell 7. The multi-junction solar cell may comprise a diffraction grating 4, low-index transparent spacer 5, and distributed Bragg reflector that are co-designed. The multi-junction solar cell may also comprise a diffraction grating 4, low-index transparent spacer 5, and distributed Bragg reflector are co-designed to the wavelength range of the target subcell 3.

In another embodiment of the invention, a multi-junction solar cell is presented in which a diffraction grating 4 is located at the top of the device, a low-index transparent spacer layer 5 is positioned beneath the target subcell 3, and a DBR 6 is located beneath the low-index transparent spacer layer 5 and above the lower subcells 7. This embodiment is denoted configuration 2b.

In yet another embodiment of the invention, the solar cell is a triple junction InGaP/InGaAs/Ge space solar cell, the target subcell 3 is the InGaAs subcell, and the optical components are positioned between the InGaAs subcell and the Ge subcell. The thickness of the InGaAs subcell is between 300 and 1000 nm, preferably between 500 and 1000 nm, the period of the diffraction grating 4 is between 200 and 1400, preferably between 300 and 600 nm, and the refractive index of the low-index transparent spacer layer 5 is between 1 and 2.5.

In yet another embodiment of the invention, the the low-index transparent spacer layer 5 comprises an air gap, since this has the required low refractive index and is transparent. An air gap should be understood to mean that the target subcells 3 are separated by the lower subcells 7 by an empty space that does not include any material.

According to yet another embodiment of the present invention, the DBR 6 comprises alternating layers of dielectric materials. Whilst in yet another embodiment the DBR 6 comprises or alternating layers of semiconductor materials.

In yet another embodiment the transparent spacer layer is omitted, since the dielectric DBR does not support oblique photon modes that can be coupled to by the periodic light scatterer, as a result of the low refractive index of the DBR.

According to yet another embodiment of the present invention, additional one or more anti-reflection layers coatings 1 are may be included between the target subcell 3 and the lower subcells 7 in order that for light in the wavelength range of the lower subcells 7 to be efficienctly transmitted into the lower subcells 7. This is to offset the increased reflection between materials in the optical components with high and low refractive indices.

Furthermore, a diffraction grating, a distributed Bragg reflector and a transparent spacer layer, may be provided in any combination which achieves the aim of improving the photocurrent or efficiency of a subcell within the multi-junction stack. This includes combinations omitting one or more of any one these components and/or combinations including more than one of any one of these components.

For example, components may be arranged such that light travelling at trajectories substantially normal to the plane of the target subcell may be deflected to travel at oblique trajectories in the target subcell. For example, a diffraction grating may be provided either directly or indirectly above the target subcell. Alternatively, or in addition, a diffraction grating may be provided either directly or indirectly below the target subcell.

In a further example, components may be arranged such that light travelling at oblique trajectories relative to the plane of the target cell may undergo total internal reflection in the target subcell. For example, a transparent spacer layer having a refractive index lower than a refractive index of the target subcell may be provided either directly or indirectly above the target subcell. Alternatively, or in addition, a transparent spacer layer may be provided either directly or indirectly below the target subcell. A distributed Bragg reflector having a refractive index lower than a refractive index of the target subcell may be used place of a transparent spacer layer to achieve the total internal reflection effect in the target subcell.

In a further example, components may be arranged such that light in a particular wavelength range and having a trajectory through the target subcell normal to the plane of the target subcell may be reflected back into the target subcell, while light outside said wavelength range may pass from the target cell into the lower subcell. For example, a distributed Bragg reflector may be provided either directly below or indirectly below the target subcell.

The present invention relates to a multi-junction solar cell comprising optical components which synergistically enhance the photocurrent of a single subcell.

As used herein, the term “diffraction grating” 4 will be understood to mean an optical component comprising a layer with a spatially periodic structure in the plane of the layer. “Spatially periodic” will be understood to mean that the grating can be described mathematically as a number of identical unit cells that are repeated throughout the layer at equal spacings.

A light beam incident on a diffraction grating 4 is split into two or more light beams, known as diffraction orders, which propagate away from the grating on either side of the grating. This is shown schematically in FIG. 11. In general, the incident light beam is split into both reflected diffraction orders and transmitted diffraction orders. Reflected diffraction orders propagate back into the medium from whence the incident beam was incident, and transmitted diffraction orders propagate on the opposite side of the grating.

The trajectories of the diffraction order are not, in general, the same as the trajectory of the incident light beam. A diffraction grating 4 can therefore be used to deflect an incident light beam into another direction in a controlled manner. In particular, an incident light beam with a trajectory perpendicular to the plane of the grating can be deflected into a diffraction order with a trajectory that is oblique with respect to the plane of the grating. The number of diffracted orders and their and trajectories are determined by the wavelength and trajectory of the incident beam, the period of the diffraction grating 4, and the refractive index of the medium in which the diffraction orders are propagating, i.e. the medium on the corresponding side of the diffraction grating 4. The fraction of the incident light intensity that is coupled into each diffraction order is determined by the geometry and materials of the repeating unit cell that constitutes the grating. The period of the diffraction grating 4 is defined as the distance between a given point on a unit cell and the equivalent point on the adjacent unit cell, and is denoted by the symbol A. A diffraction grating 4 may be periodic in either one or two dimensions in the plane of the layer. It may also be periodic in the dimension out of the plane of the layer; however, this latter periodicity does not affect the trajectories of the diffraction orders.

The invention relates more specifically to improving the photocurrent of a target subcell 3 that has a low carrier diffusion length, compared to the photon penetration depth, and that would therefore otherwise produce a low photocurrent. The target subcell 3 material may exemplarily comprise highly strained or relaxed materials, such as strained InGaAs; highly mismatched alloys, such as, but not limited to GaAsN, GaInAsN, GaInAsNSb, GaAsNSb, GaAsBi, GaInAsBi, GaAsNBi or GaInAsNBi; or indirect materials, such as SiGeSn, SiGe, Si or Ge. The target subcell 3 may also be any subcell of a multi-junction space solar cell with a photocurrent that is reduced during space missions as a result of high-energy irradiation. Examples of the target subcell 3 for space applications may include GaInP and GaInAs, as well as those already listed.

The optical components cause incident photons in the wavelength range of the target subcell 3 to pass through the target subcell 3 several times, so that they are strongly absorbed in the target subcell 3, and not in other regions of the device. This allows the thickness of the target subcell 3 to be reduced by a factor of 5, compared to the thickness that would otherwise be required to absorb close to 100% of the incident photons in the absence of the optical components. Absorbing close to 100% of the incident photons in a thinner subcell means that many more of the photogenerated charge carriers reach the space charge region at the top of the subcell before recombining, and are therefore extracted as useful electrical current. This increases the overall photocurrent generated by the target subcell 3. If the solar cell is to be used in space, this also causes the reduction of the photocurrent as a consequence of high-energy irradiation to proceed at a lower rate, since a thinner subcell is more tolerant to a reduction in charge-carrier diffusion lengths,

The optical components comprise;
A diffraction grating 4. This may consist of a textured layer that is spatially periodic, or a spatially-periodic array of isolated particles. The textured layer or particles may consist of semiconductor materials: ideally wide-bandgap materials such as AlInP, GaInP or a-Si:H, as they are transparent over the wavelength range of the target subcell 3. They may also comprise metallic materials to give strong scattering due to the excitation of surface plasmon polaritons.
A transparent spacer layer 5. This layer preferably has a lower refractive index than the semiconductor material of the target subcell 3, i.e. between 1 and 2.5. Materials that satisfy these requirements include SiOx, SiNx, AlOx, TiOx, MgFx and TaOx. The transparent layer 5 may also be an air gap. The transparent spacer layer 5 may also be a transparent conductive oxide, such as tin-doped indium-oxide (ITO), or aluminium-doped zinc-oxide (AZO). The transparent spacer layer 5 confines photons into a single diffraction order with a normal trajectory.
A distributed Bragg reflector (DBR) 6, which comprises alternating layers of two materials with distinct refractive indices. The materials may be semiconductors, in which case the high-refractive-index material may be GaAs and the low-refractive-index material may be AlAs or AlInP. The materials may also be dielectrics, in which case the high-refractive-index material may be TiOx, TaOx or SiN, and the low-refractive-index material may be MgFx, SiO2 or AlOx, where a further advantage of employing these materials is that they are fully transparent over the wavelength range of the target subcell 3. The DBR 6 may also comprise transparent conductive oxides, such as tin-doped indium-oxide (ITO), or aluminium-doped zinc-oxide (AZO). The DBR 6 may also comprise a combination of semiconductor and dielectric materials. The DBR 6 is engineered to reflect photons in the wavelength range that coincides with the wavelength range of the target subcell 3, and to transmit photons in the wavelength range that coincides with the wavelength range of the lower subcells 7.

The combination of optical components is wavelength selective, in that it acts differently on photons in the wavelength range of the target subcell 3 and on photons in the wavelength range of the lower subcells 7. Photons in the wavelength range of the target subcell 3 are made to pass through the target subcell 3 many times, such that they are strongly absorbed there. In doing so, these photons may also pass many times through the upper subcells 2, which are transparent in this wavelength range. However, these photons will be prevented from penetrating into the lower subcells 7, which are absorbing in this wavelength range. On the other hand, photons in the wavelength range corresponding to the lower subcells 7 may penetrate into the lower subcells 7 with minimal hindrance.

The invention may be realised as a two-terminal device. In such embodiments the diffraction grating 4, transparent spacer layer 5 and DBR 6 are preferably electrically conductive. In the two-terminal device, the diffraction grating comprises semiconductor material, the transparent spacer layer 5 comprises a transparent conductive oxide, and the DBR comprises a semiconductor material. Transparent conductive oxides are preferable as the transparent spacer layer in a two-terminal device as it is conductive, has a low refractive index, and is transparent, and thus has the optical functionality of a transparent spacer. The transparency of the conductive oxides allows current to flow through the device. In the two-terminal device embodiment, there are preferably no lateral conduction layers, since the two terminals are at the top and bottom of the device.

The device may be realised as a four-terminal device. In such an embodiment the diffraction grating 4, transparent spacer layer 5 or DBR 6 are preferably electrically insulating. As the diffraction grating 4, transparent spacer layer 5, or DBR 6 are not required to be electrically conductive, the transparent spacer layer may not be a transparent conductive oxide. It is preferable however, to have lateral conduction layers, that have no light-trapping function, which serve to transport current to the terminals at the edge of the device. In a four-terminal device the one or more upper-subcells 2, and target subcells 3 have one pair of terminals and the lower subcells 7 have another pair of terminals.

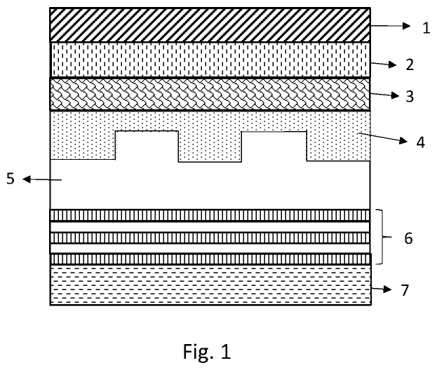

In one embodiment of the invention, the optical components are positioned in the device as shown in FIG. 1. The diffraction grating 4 is located beneath the target subcell 3, the transparent spacer layer 5 is positioned beneath the diffraction grating 4, and the DBR 6 is located beneath the transparent spacer layer 5 and above the lower subcells 7. This embodiment is denoted configuration a.

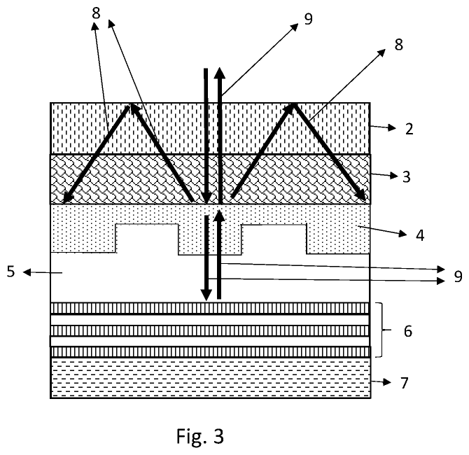

The arrows in FIG. 3 represent the trajectories of photons in the wavelength range of the target subcell 3 upon entering into the device in configuration a. The photons enter the device from the top and pass through the upper subcells 2 and the target subcell 3, being partially absorbed in the target subcell 3. The photons then reach the diffraction grating 4 and are deflected into a number of diffraction orders. Due to the period of the diffraction grating 4 and the refractive index of the transparent spacer layer 5, there is only a single diffraction order in the transparent spacer layer 5, which has a normal trajectory 9, whereas there are many diffraction orders in the in the target subcell 3, one of which has a normal trajectory 9, and the rest of which have oblique trajectories 8. The diffraction orders with oblique trajectories 8 are totally internally reflected at the interface at the top of the device, and pass a second time through the upper subcell 2 and the target subcell 3, thus increasing the light absorption in the target subcell 3. The diffraction orders are again incident on the diffraction grating 4 and most are deflected back into the target subcell 3, giving a third, fourth and subsequent opportunities for absorption. The single diffraction order in the transparent spacer layer 5 has a trajectory that is normal to the underlying DBR 6. Also, the stop-band of the DBR 6 encompasses the wavelength range corresponding to the target subcell 3. Therefore, this order is reflected back to the diffraction grating 4, where it has another opportunity to be deflected into the target subcell 3. These processes continue, causing the photons to make multiple passes of the target subcell 3, significantly increasing the photogeneration in the target subcell 3.

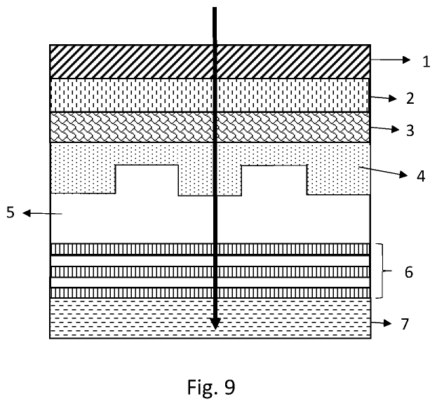

The arrows in FIG. 9 represent the trajectories of photons in the wavelength range of the lower subcells 7 upon entering into the device in configuration a. In this wavelength range, due to the period of the diffraction grating 4, the diffraction grating 4 does not deflect the photons into any oblique diffraction orders, and they are instead transmitted with normal trajectory 9 into the transparent spacer layer 5. They are then transmitted through the DBR 6 into the lower subcells 7, since they are not in the stop-band of the DBR 6.

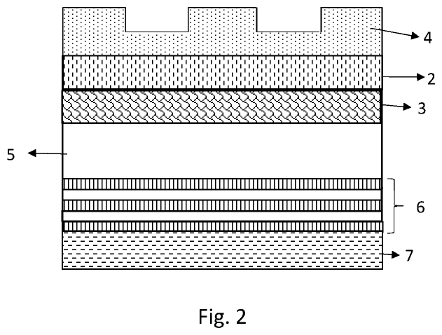

In another embodiment of the invention, the optical components are positioned in the device as shown in FIG. 2. The diffraction grating 4 is located on the top of the device, the transparent spacer layer 5 is positioned beneath the target subcell 3, and the DBR 6 is located beneath the transparent spacer layer 5 and above the lower subcells 7. This embodiment is denoted configuration b. In this embodiment, the diffraction grating 4 is also designed to reduce reflection at the front surface, so that sunlight enters into the device. This is achieved by embedding the diffraction grating 4 in an anti-reflection coating 1, or by making the diffraction grating 4 comprise multiple layers with different refractive indices to reduce reflection.

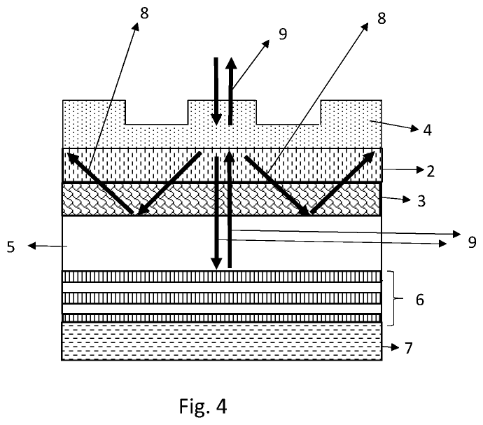

The arrows in FIG. 4 represent the trajectories of photons in the wavelength range of the target subcell 3 upon entering into the device in configuration b. The photons enter the device from the top, are immediately incident on the diffraction grating 4, and are deflected into a number of diffraction orders. Due to the period of the diffraction grating 4 and the refractive index of the transparent spacer layer 5, there is only a single diffraction order that escapes the device, whereas there are many diffraction orders that penetrate into the device, one of which has a normal trajectory 9, and the rest of which have oblique trajectories 8. The diffraction orders with oblique trajectories 8 are totally internally reflected at the interface between the target subcell 3 and the transparent spacer layer 5. The diffraction order with a normal trajectory 9 penetrates into the transparent spacer layer 5, and is reflected by the DBR 6. All orders are therefore efficiently reflected back into the target subcell 3, giving them a second opportunity to be absorbed. Those that are still not absorbed pass again through the upper subcells 2 and are incident on the diffraction grating 4, which deflects most of these photons back into the device, giving them a third and fourth opportunity to be absorbed. This process continues causing the photons to make multiple passes of the target subcell 3, significantly increasing the photogeneration in the target subcell 3.

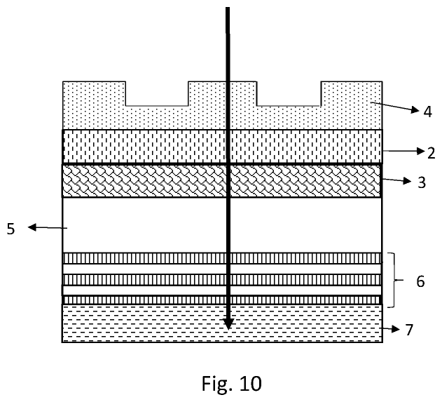

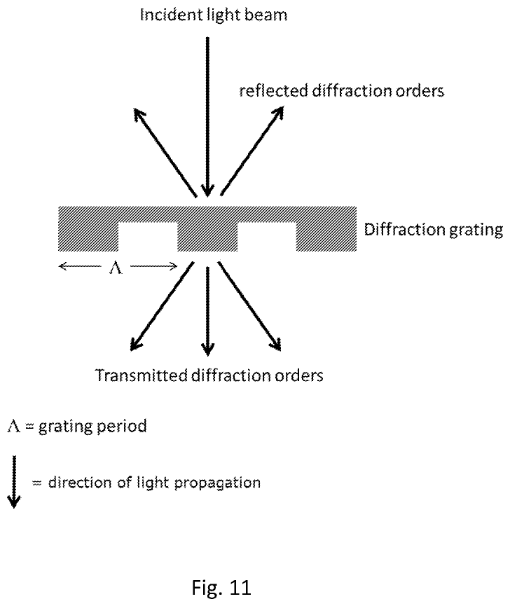

The arrows in FIG. 10 represent the trajectories of photons in the wavelength range of the lower subcells 7 upon entering into the device in configuration b. In this wavelength range, due to the period of the diffraction grating 4, the diffraction grating 4 does not deflect the photons into any oblique diffraction orders, and they are instead transmitted with normal trajectory 9 into the transparent spacer layer 5. They are then transmitted through the DBR 6 into the lower subcells 7, since they are not in the stop-band of the DBR 6.

In both configurations, the diffraction grating 4, transparent spacer layer 5 and DBR 6 are co-designed to achieve the wavelength-selective light trapping effect described above. The period of the diffraction grating 4 is co-designed such that, in the wavelength range of the target subcell 3, many diffraction orders propagate in the target subcell 3, but only a single diffraction order propagates in the transparent spacer layer 5. The latter diffraction order has a normal trajectory 9. This is crucial to the invention, since the DBR 6 can only effectively reflect normal-trajectory photons. To achieve this effect, the transparent spacer layer 5 preferably has a low refractive index, of less 2.5, and more preferably less than 2. The period of the diffraction grating 4, A, is preferably approximately equal to

$$Λ \approx \frac{{λ}_{0}}{n} \qquad ( Eqn . 1 )$$

where n is the refractive index of the transparent spacer layer 5, and λ₀ is the lowermost wavelength at which more than 10% of photons incident from the sun reach the diffraction grating 4. λ₀ can be calculated from

$$α ( {λ}_{0} ) \approx \frac{ln 10}{d} \qquad ( Eqn . 2 )$$

where α(λ₀) is the absorption coefficient of the target subcell 3 at wavelength λ₀ and d is the thickness of the target subcell 3.

The optical components cause the optical path length inside the target subcell 3 to increase by a factor between 3 and 10. Therefore, the thickness of the target subcell 3 is preferably between 1/3 and 1/10 times the thickness that would otherwise be required to absorb close to 100% of the photons in the corresponding wavelength range in the absence of the optical components. Therefore, if the target subcell 3 is GaAs, or In_{0.1}Ga_{0.9}As, the thickness of the target subcell 3 is preferably in the range 600-800 nm, but can be in the range 300-1000 nm. Similar thickness ranges are expected for other III-V materials. A III-V material should be understood to mean a material comprising elements from group III of the periodic table to elements from group V of the periodic table. It will be appreciated that the III-V material may refer to a material consisting of elements from group III of the periodic table to elements from group V of the periodic table.

If the target subcell 3 is GaAs, or In_{0.1}Ga_{0.9}As, and the transparent spacer layer 5 has a refractive index of 1.5, the optimum period calculated from Eqns 1 and 2 is A=450 nm, and the preferable range of periods is 300-550 nm. If the target subcell 3 is GaAs, or In_{0.1}Ga_{0.9}As, and the transparent spacer layer 5 is an air gap, with a refractive index of 1, the optimum period calculated from Eqns 1 and 2 is ∧=700 nm, and the preferable range of periods is 500 nm 1000 nm. The preferable range of periods is therefore 300-1000 nm if the target subcell 3 is GaAs, or In_{0.1}Ga_{0.9}As.

If the target subcell 3 is another material, the optimum period will change depending on the bandgap of the material. If the target subcell 3 is based on a material with a bandgap close to 1 eV (eg. In_{0.3}Ga_{0.9}As, GaAsN, GaInAsN, GaInAsNSb, GaAsNSb, GaAsBi, GaInAsBi, GaAsNBi or GaInAsNBi), and the transparent spacer layer 5 has a refractive index of 1.5, then the preferable range of grating periods is 400-800 nm. If the target subcell 3 is based on a material with a bandgap close to 1 eV (eg. In_{0.3}Ga_{0.9}As, GaAsN, GaInAsN, GaInAsNSb, GaAsNSb, GaAsBi, GaInAsBi, GaAsNBi or GaInAsNBi), and the transparent spacer layer 5 is an air gap, with a refractive index of 1, then the preferable range of grating periods is 700-1400 nm. If the target subcell 3 is based on a material with a bandgap close to 2 eV (eg. GaInP or AlInP), and the transparent spacer layer 5 has a refractive index of 1.5, then the preferable range of grating periods is 200-400 nm. If the target subcell 3 is based on a material with a bandgap close to 2 eV (eg. GaInP or AlInP), and the transparent spacer layer 5 is an air gap, with a refractive index of 1, then the preferable range of grating periods is 350-700 nm.

By choosing the grating period to satisfy Eqn. 1, it is also achieved that, in the wavelength range corresponding to the lower subcells 7, the diffraction grating 4 does not deflect photons into any oblique diffraction orders anywhere in the device. Hence photons in this wavelength range are not reflected at the interface between the target subcell 3 and the transparent spacer layer 5.

The wavelength range of the stop-band of the DBR 6 is such that its upper wavelength limit approximately coincides with the upper wavelength limit of the wavelength range of the target subcell 3. If the target subcell 3 is GaAs, or In_{0.1}Ga_{0.9}As, then the stop-band of the DBR 6 is preferably of from 700-900 nm. If the target subcell 3 is based on a material with a bandgap close to 1 eV (eg. In_{0.3}Ga_{0.9}As, GaAsN, GaInAsN, GaInAsNSb, GaAsNSb, GaAsBi, GaInAsBi, GaAsNBi or GaInAsNBi), then the stop-band of the DBR 6 is preferably 1000-1250 nm. If the target subcell 3 is based on a material with a bandgap close to 2 eV (eg. GaInP or AlInP), then the stop-band of the DBR 6 is preferably of from 500-650 nm.

According to yet another embodiment of the present invention, the DBR comprises layers of alternating dielectric materials, and the transparent spacer layer is omitted, since the dielectric DBR does not support oblique photon modes that can be coupled to by the periodic light scatterer, as a result of the low refractive index of the DBR.

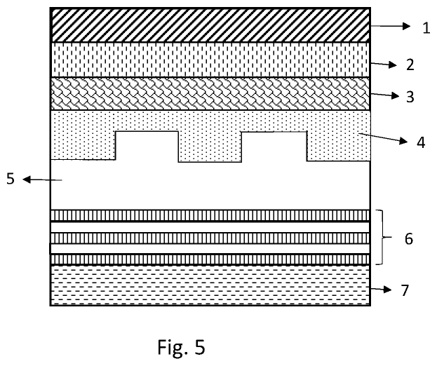

FIG. 5 shows an embodiment of the invention, wherein the host solar cell is an InGaP/InGaAs/Ge space solar cell. Here, the target subcell 3 is the InGaAs subcell, and the optical components are positioned between the InGaAs subcell and the Ge subcell. The thickness of the InGaAs subcell is preferably between 650 and 750 nm, but can be between 500 nm and 1000 nm. A computational simulation has been made of this embodiment of the invention. In the simulation, the InGaAs subcell thickness is set to 700 nm.

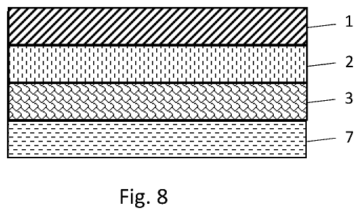

FIG. 8 shows a control device that is also simulated as a benchmark to the invention. In the simulation, the thickness of the InGaAs subcell in the control device is set to 3500 nm, which is roughly the thickness required to absorb close to 100% of the incident photons in the corresponding wavelength range in the absence of optical components.

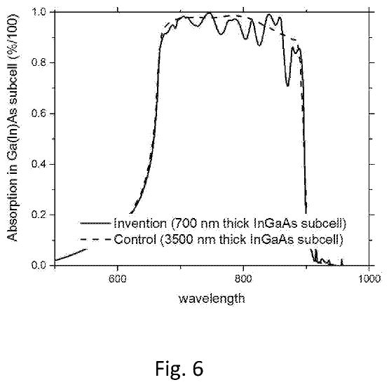

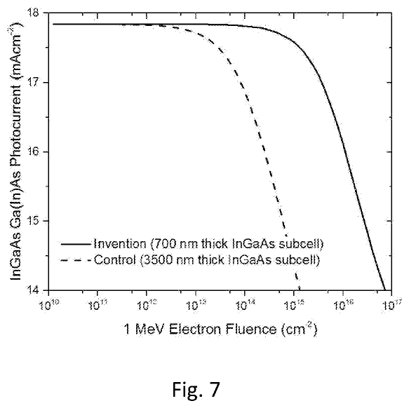

The solid line in FIG. 6 shows the calculated absorption in the InGaAs subcell in the present invention, whereas the dashed line shows the calculated absorption in the InGaAs subcell in the control device. The absorption is calculated using a rigorous coupled wave analysis algorithm. Under illumination by the AM0 extraterrestrial spectrum, the total photon absorption in the InGaAs subcell in this embodiment of the invention is calculated to be 1.15×10²⁰ cm⁻²s⁻¹, whereas in the control device it is calculated to be 1.18×10²⁰ cm⁻²s⁻¹. This shows that the invention allows the InGaAs subcell to be thinned to about 700 nm whilst maintaining a similar absorption to what would otherwise be absorbed if its thickness were about 3500 nm. This is around a 5-fold decrease in the thickness required to absorb nearly 100% of incident photons in the relevant wavelength range.

FIG. 7 shows the calculated InGaAs photocurrent of this embodiment of the invention as a function of high-energy (1 MeV) electron fluence compared to the control device. A typical irradiation level for Geospace mission is about 10¹⁵ cm⁻². The photocurrent is calculated using a rigorous coupled wave analysis algorithm coupled to an analytical one-dimensional drift-diffusion solver.

The device designs shown in configurations a and b can be grown as mechanical stacks, in which the lower subcells 7 are grown on one substrate, and the target subcell 3 and upper subcells 2 are grown on a separate substrate. This increases the fabrication complexity compared to the monolithic structures presently favoured by industry. However, it is necessary to allow access to the interface beneath one of the middle subcells. Steiner et. al. reported on a four-terminal mechanical stack that was fabricated with a layer of epoxy between the upper and lower tandems, in order to promote luminescent photon recycling (see Steiner, M. A., et al., Photovoltaic Specialist Conference (PVSC), 2015 IEEE 42nd (2015)). In the present invention, we use the process of Steiner et al (2015) as a baseline for fabricating the structure presented in the present invention.

A method for fabricating the device design shown in FIG. 1 is described as follows. The lower subcells 7 are grown upright on a substrate. Upright means that the ordering of the subcells, from top to bottom, is the same as their ordering in the finalised device. The DBR 6 is grown above the bottom cells. If the DBR 6 comprises crystalline semiconductor materials, the DBR 6 may be grown epitaxially. It will be appreciated that if the DBR 6 consists of crystalline semiconductor materials, the DBR 6 may be grown epitaxially If the DBR 6 comprises dielectric materials, amorphous semiconductor materials, transparent conductive oxides, or a combination thereof, the DBR 6 may be grown by chemical vapour deposition, sputtering or evaporation. It will be appreciated that if the DBR 6 consists of dielectric materials, amorphous semiconductor materials, transparent conductive oxides, or a combination thereof, the DBR 6 may be grown by chemical vapour deposition, sputtering or evaporation. The upper- and target subcells 3 are grown inverted on a separate substrate. Inverted means that the ordering of the subcells, from top to bottom, is the reverse of their ordering in the finalised device; therefore, the target subcell 3 is grown above the upper subcells 2. The diffraction grating 4 is then realised above the target subcell 3 using one of the methods described further on. The transparent spacer layer 5 is then grown above the diffraction grating 4 by chemical vapour deposition, sputtering or evaporation. Finally, the stack comprising the upper- and target subcells 3, the diffraction grating 4 and the transparent spacer layer 5 is turned upside down and bonded to the stack comprising the lower subcells 7 and the DBR 6. It will be appreciated that the stack consisting of the upper- and target subcells 3, the diffraction grating 4 and the transparent spacer layer 5 is turned upside down and bonded to the stack consisting of the lower subcells 7 and the DBR 6. The substrate on which the upper- and target subcells 3 were grown is then removed, and the anti-reflection coating 1 is deposited above the upper subcells 2.

A method for fabricating the device design shown in FIG. 2 is described as follows. The lower subcells 7 are grown upright on a substrate. The DBR 6 is grown above the bottom cells as described in the preceding paragraph. The upper- and target subcells 3 are grown inverted on a separate substrate. The transparent spacer layer 5 is then grown above the target subcell 3. Then, the stack consisting of the upper- and target subcells 3 and the transparent spacer layer 5 is turned upside down and bonded to the stack consisting of the lower subcells 7 and the DBR 6. The substrate on which the upper- and target subcells 3 were grown is then removed. The diffraction grating 4 is then realised above the upper subcells 2 using one of the methods described further on. Possible methods for realising the diffraction grating 4 are described as follows. If the diffraction grating 4 comprises crystalline semiconductor materials, a layer of the comprising material is grown above the corresponding subcell epitaxially; this layer is then patterned by a high-throughput replication technique such as nano-imprint lithography followed by reactive ion etching (see H. Hauser, et al., “Diffractive Backside Structures via Nanoimprint Lithography,” Energy Procedia, 27(0), 337-342 (2012)). Deep ultraviolet lithography can also be used as an alternative to nanoimprint lithography. If the diffraction grating 4 comprises amorphous semiconductor materials, metallic materials, or high-index dielectric materials then the diffraction grating 4 can be realised by two methods. The first is the method described above for crystalline semiconductor materials, but replacing the crystalline semiconductor material with the comprising material and replacing epitaxial deposition with chemical vapour deposition, sputtering or evaporation. The second is by nano-imprint lithography followed by a lift-of process (see Meisenheimer, S.-K., et al., Opt. Mater. Express 4 (2014) 944-952).

The following clauses are also disclosed:

Clause 1. A multi-junction solar cell comprising three or more subcells, at least three optical components, and transparent conduction layers, wherein the subcells comprise upper subcells and lower subcells.
Clause 2. A multi-junction solar cell according to clause 1, wherein at least one of the subcells is a target subcell.
Clause 3. The multi-junction solar cell according to clause 2 wherein the target subcell is any of the subcells, except for the lower-most subcell.
Clause 4. The multi-junction solar cell of any of the preceding clauses wherein one or more subcells comprise group III-V materials.
Clause 5. The multi-junction solar cell according to clause 4 wherein the III-V compounds are selected from the group consisting of InGaP, AlInP, GaAs, InGaAs, GaAsN, GaAsSb, GaAsNSb, GaAsInN, GaAsInNSb, GaAsBi, or GaAsBiN.
Clause 6. The multi-junction solar cell of any of the preceding clauses wherein one or more subcell comprises group IV materials.
Clause 7. The multi-junction solar cell according to clause 6 wherein the group IV materials are selected from the group consisting of Ge, Si, SiGe, SiGeSn.
Clause 8. The multi-junction solar cell according to any of clauses 2 to 7 wherein the target subcell has a wavelength range corresponding to the wavelength range of the subcell material.
Clause 9. The multi-junction solar cell according to any of the preceding clauses wherein the optical components comprise;
a) a diffraction grating;
b) a transparent spacer layer; and
c) a distributed Bragg reflector (DBR).
Clause 10. The multi-junction solar cell according to clause 9, wherein the diffraction grating is located beneath the target subcell, the transparent spacer layer is positioned beneath the diffraction grating, and the DBR is located beneath the transparent spacer layer.
Clause 11. The multi-junction solar cell according to any of the preceding clauses, wherein the optical components are positioned between two adjacent subcells.
Clause 12. A multi-junction solar cell according to any of clauses 9-11, wherein the diffraction grating is positioned in front of the top-most subcell, the transparent spacer layer is positioned beneath the target subcell, and the DBR is positioned beneath the transparent spacer layer and above the lower subcells.
Clause 13. A multi-junction solar cell according to any of clauses 9-12, wherein the diffraction grating is embedded in an anti-reflection coating.
Clause 14. A multi-junction solar cell according to any of clauses 9-13, wherein the diffraction grating comprises multiple layers with different refractive indices.
Clause 15. A multi-junction solar cell according to any of clauses 9-14, wherein the diffraction grating comprises a grating period.
Clause 16. The multi-junction solar cell according to any of clauses 9-15, wherein the diffraction grating comprises a textured layer.
Clause 17. The multi-junction solar cell according to clause 16, wherein the textured layer comprises a spatially-periodic array of isolated particles.
Clause 18. The multi-junction solar cell according to any of clauses 9-17, wherein the diffraction grating comprises wide-bandgap semiconductor materials selected from the group consisting of AlInP, GaInP or a-Si:H.
Clause 19. The multi-junction solar cell according to any of clauses 9-18, wherein the diffraction grating comprises metallic materials selected from the group consisting of Al, Ag or Au.
Clause 20. The multi-junction solar cell according to any of clauses 9-19, wherein the textured layer material is selected from the group consisting of AlInP, GaInP, InGaAs, GaAs or Si.
Clause 21. The multi-junction solar cell according to any of clauses 9-20, wherein the diffraction grating comprises a grating period in the range 200-1400 nm.
Clause 22. The multi-junction solar cell according to any of clauses 9-21, wherein an electrically insulating layer is positioned between the diffraction grating and the subcell immediately in front of it.
Clause 23. The multi-junction solar cell according to any of clauses 9-22, wherein the transparent spacer layer is selected from the group consisting of SiOx, TiOx, MgFx, TaOx, AlOx or SiN.
Clause 24. The multi-junction solar cell according to any of clauses 9-23, wherein the transparent spacer layer has a refractive index between 1 and 2.5 over the wavelength range of the target cell.
Clause 25. The multi-junction solar cell according to any of clauses 9-24, wherein the transparent spacer layer is an air gap.
Clause 26. The multi-junction solar cell according to any of clauses 9-25, wherein the transparent spacer layer is omitted.
Clause 27. The multi-junction solar cell according to any of clauses 9-26, wherein the DBR comprises alternating layers of different semiconductor materials.
Clause 28. The multi-junction solar cell according to any of clauses 9-27, wherein the DBR comprises of alternating layers of different dielectric materials.
Clause 29. The multi-junction solar cell according to any of clauses 9-28, wherein the DBR comprises two materials with different refractive indices, wherein one refractive index is higher, and one refractive index is lower than the other.
Clause 30. The multi-junction solar cell according to clause 29 wherein the higher refractive index material is selected from the group consisting of GaAs, TiOx, TaOx or SiN.
Clause 31. The multi-junction solar cell according to any of clauses 29-30 wherein the lower refractive index material is selected from the group consisting of AlAs, GaInP, MgFx, SiO2 or AlOx.
Clause 32. The multi-junction solar cell according to any of clauses 9-31, wherein the DBR comprises a combination of dielectric and semiconductor materials
Clause 33. The multi-junction solar cell according to any of the preceding clauses in which the solar cell is a four-terminal device.
Clause 34. The multi-junction solar cell according to any of the preceding clauses wherein the solar cell is a triple-junction InGaP/InGaAs/Ge space solar cell, formed of subcells InGaP, InGaAs and Ge.
Clause 35. The multi-junction solar cell according to clause 34 wherein the optical components are positioned between the InGaAs subcell and the Ge subcell, wherein the target subcell is the InGaAs subcell.
Clause 36. The multi-junction solar cell according to any of clauses 2-35, wherein the thickness of the target subcell is in the range 300-1000 nm.
Clause 37. The multi-junction solar cell according to any of clauses 2-36, wherein anti-reflection layers are included between the target subcell and the lower subcells.
Clause 38. The multi-junction solar cell according to any of the preceding clauses wherein the transparent lateral conduction layers are positioned on the rear of the subcell.
Clause 39. The multi-junction solar cell according to any of the preceding clauses wherein the transparent lateral conduction layers are positioned immediately in front of the optical components.
Clause 40. The multi-junction solar cell according to any of the preceding clauses wherein the transparent lateral conduction layers are positioned on the front of the subcell immediately behind the optical components.
Clause 41. A method of fabricating a multi-junction solar cell according to any of clauses 1-40, wherein a two-substrate mechanical stacking process is combined with a nanotexturing deposition or a nanoparticle deposition.
Clause 42. A method of fabricating a multi-junction solar cell according to clause 41, wherein the nanoparticles are arranged between the subcells of the device.
Clause 43. A method of fabricating a multi-junction solar cell according to any of clauses 41-42 wherein the nanotexturing is arranged between the subcells of the device.
Clause 44. A method of fabricating a multi-junction solar cell according to any of clause 41-43 wherein the subcells in front of the optical components and the subcells behind the optical components are grown on separate substrates and bonded together to form a mechanical stack with the optical components in-between the two sets of subcells.
Clause 45. Use of a multi-junction solar cell according to any of clauses 1-40 in terrestrial applications, space applications, a concentrator voltaic module, a satellite, a solar panel or in terrestrial solar power generators.
Clause 46. Use of a multi-junction solar cell according to any of clauses 1-40 in a kit comprising: a solar panel, a power subsystem; and a satellite.

1. A multi-junction solar cell comprising:
a target subcell,
a diffraction grating,
a transparent spacer layer,
a distributed Bragg reflector, and
a lower subcell.

2. The multi-junction solar cell according to claim 1, wherein the target subcell is above the lower subcell.

3. The multi-junction solar cell according to claim 1 or 2, wherein the transparent spacer layer is below the target subcell, and wherein the distributed Bragg reflector is below the transparent spacer layer.

4. The multi-junction solar cell according to claim 3, wherein the transparent spacer layer and the distributed Bragg reflector are above the lower subcell.

5. The multi-junction solar cell according to claim 3 or 4, wherein the diffraction grating is below the target subcell, and the transparent spacer layer is below the diffraction grating.

6. The multi-junction solar cell according to claim 3 or 4, wherein the diffraction grating is at the top of the multi-junction solar cell.

7. The multi-junction solar cell according to any preceding claim, wherein the diffraction grating is arranged to deflect an incident light beam with a trajectory perpendicular to a plane of the diffraction grating into diffraction orders having trajectories oblique with respect to said plane.

8. The multi-junction solar cell according to any preceding claim, wherein the target subcell has a first refractive index and the transparent spacer layer has a second refractive index lower than the first refractive index.

9. The multi-junction solar cell according to any preceding claim, wherein at least one of the target subcell and the lower subcell comprises group III-V materials.

10. The multi-junction solar cell according to claim 9, wherein the group III-V materials are selected from the group consisting of InGaP, AlInP, GaAs, InGaAs, GaAsN, GaAsSb, GaAsNSb, GaAsInN, GaAsInNSb, GaAsBi, and GaAsBiN.

11. The multi-junction solar cell according to any preceding claim, wherein at least one of the target subcell and the lower subcell comprises group IV materials.

12. The multi-junction solar cell according to claim 11, wherein the group IV materials are selected from the group consisting of Ge, Si, SiGe, and SiGeSn.

13. A multi-junction solar cell according to any preceding claim, wherein the diffraction grating is embedded in an anti-reflection coating.

14. A multi-junction solar cell according to any preceding claim, wherein the diffraction grating comprises multiple layers with different refractive indices.

15. The multi-junction solar cell according to any preceding claim, wherein the diffraction grating comprises a textured layer.

16. The multi-junction solar cell according to claim 15, wherein the textured layer comprises a spatially-periodic array of isolated particles.

17. The multi-junction solar cell according to claim 15 or 16, wherein the textured layer comprises a material selected from the group consisting of AlInP, GaInP, InGaAs, GaAs and Si.

18. The multi-junction solar cell according to any preceding claim, wherein the diffraction grating comprises semiconductor materials selected from the group consisting of AlInP, GaInP and a-Si:H.

19. The multi-junction solar cell according to any preceding claim, wherein the diffraction grating comprises metallic materials selected from the group consisting of Al, Ag and Au.

20. The multi-junction solar cell according to any preceding claim, wherein the diffraction grating comprises a grating period in the range 200-1400 nm.

21. The multi-junction solar cell according to any preceding claim, further comprising an electrically insulating layer between the diffraction grating and the target subcell.

22. The multi-junction solar cell according to any preceding claim, wherein the transparent spacer layer is selected from the group consisting of SiOx, TiOx, MgFx, TaOx, AlOx and SiN.

23. The multi-junction solar cell according to any preceding claim, wherein the transparent spacer layer is an air gap.

24. The multi-junction solar cell according to any preceding claim, wherein the distributed Bragg reflector comprises alternating layers of different semiconductor materials.

25. The multi-junction solar cell according to any preceding claim, wherein the distributed Bragg reflector comprises alternating layers of different dielectric materials.

26. The multi-junction solar cell according to any preceding claim, wherein the distributed Bragg reflector comprises two materials with different refractive indices, wherein one refractive index is higher, and one refractive index is lower than the other, wherein the higher refractive index material is selected from the group consisting of GaAs, TiOx, TaOx and SiN.

27. The multi-junction solar cell according to any preceding claim, wherein the distributed Bragg reflector comprises two materials with different refractive indices, wherein one refractive index is higher, and one refractive index is lower than the other, wherein the lower refractive index material is selected from the group consisting of AlAs, GaInP, MgFx, SiO₂ and AlOx.

28. The multi-junction solar cell according to any preceding claim, wherein the distributed Bragg reflector comprises a combination of dielectric and semiconductor materials.

29. The multi-junction solar cell according to any preceding claim in which the multi-junction solar cell is a four-terminal device.

30. The multi-junction solar cell according to any of claims 1-5, wherein the multi-junction solar cell is a triple-junction InGaP/InGaAs/Ge space solar cell, formed of subcells comprising InGaP, InGaAs and Ge.

31. The multi-junction solar cell according to claim 30, wherein the transparent spacer layer, the diffraction grating and the distributed Bragg reflector are positioned between the InGaAs subcell and the Ge subcell, wherein the target subcell is the InGaAs subcell.

32. The multi-junction solar cell according to any preceding claim, wherein the thickness of the target subcell is in the range 300-1000 nm.

33. The multi-junction solar cell according to any preceding claim, further comprising anti-reflection layers between the target subcell and the lower subcell.

34. A method of fabricating a multi-junction solar cell according to any of claims 1-33, wherein a two-substrate mechanical stacking process is combined with a nanotexturing deposition or a nanoparticle deposition process.

35. A method of fabricating a multi-junction solar cell according to claim 34, wherein the nanoparticles are arranged between the target subcell and the lower subcell.

36. A method of fabricating a multi-junction solar cell according to claim 34 or 35, wherein the nanotexturing is arranged between the target subcell and lower subcell.

37. A method of fabricating a multi-junction solar cell according to any of claim 34-36, wherein the target subcell and the lower subcell are grown on separate substrates and bonded together to form a mechanical stack with the distributed Bragg reflector and transparent spacer layer in-between the target subcell and the lower subcell.

38. Use of a multi-junction solar cell according to any of claims 1-33 in terrestrial applications, space applications, a concentrator voltaic module, a satellite, a solar panel or in terrestrial solar power generators.

39. Use of a multi-junction solar cell according to any of claims 1-33 in a kit comprising:
a solar panel,
a power subsystem, and
a satellite.
